(19) United States
(12) Patent Application Publication
(10) Pub. No.: US 2008/0237655 A1
(43) Pub. Date: Oct. 2, 2008

(54) SEMICONDUCTOR APPARATUS AND METHOD FOR MANUFACTURING SAME

(75) Inventors: Yukio NAKABAYASHI, Kanagawa-ken (JP); Atsuhiro Kinoshita, Kanagawa-ken (JP); Junji Koga, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/053,873

(22) Filed: Mar. 24, 2008

(30) Foreign Application Priority Data
Mar. 29, 2007 (JP) 2007-086972

(51) Int. Cl. H01L 27/12; H01L 21/84

(52) U.S. Cl. 257/255; 257/347; 438/151; 257/E27.112

(57) ABSTRACT

A semiconductor apparatus includes: a support substrate made of a semiconductor; an insulating layer provided on the support substrate and having a first and a second openings; a semiconductor fin having a channel section, a first and second buried regions, a source section and a drain section; a gate insulating film covering a side face of the channel section; and a gate electrode opposed to the side face of the channel section across the gate insulating film. The channel section is provided upright on the insulating layer between the first and the second openings. The first and the second buried regions are provided in the first and the second openings on both sides of the channel section. The source-drain sections are provided on the first and the second buried regions and connected to the channel section.

### CROSS-REFERENCE TO RELATED APPLICATIONS

This application is based upon and claims the benefit of priority from the prior Japanese Patent Application No. 2007-086972, filed on Mar. 29, 2007; the entire contents of which are incorporated herein by reference.

### BACKGROUND OF THE INVENTION

1. Field of the Invention

This invention relates to a semiconductor apparatus having a structure of a MIS (metal insulator semiconductor) field-effect transistor, specifically a Fin-type channel transistor, used for constituting semiconductor integrated circuits, and a method for manufacturing the same.

2. Background Art

In order to enhance the performance of an LSI, it is important to improve the performance of its basic constituent device, a field-effect transistor (FET). Past improvements of device performance have been led by device downscaling, but its future limit is pointed out. The performance of an FET is determined by the largeness of drive current during on-operation and the smallness of channel leakage current during turn-off. According to the International Semiconductor Roadmap, a plurality of breakthrough technologies are required to achieve a large drive current and a small leakage current in the 45-nanometer generation and beyond.

With regard to the reduction of leakage current, an FD (fully-depleted) device, in which the channel region is fully depleted, is promising as a basic device structure in the next generation because of its high immunity to the short channel effect. In particular, attention is drawn to a transistor based on a thin film SOI (silicon on insulator) substrate and a Fin-type channel transistor.

A Fin-type channel transistor is a kind of multigate transistor, which has a channel shaped like a plate (fin) standing perpendicular to the substrate. The name “Fin-type channel transistor” is derived from the shape of the channel region.

Several problems are to be solved for obtaining a large drive current in the Fin-type channel transistor. One problem is related to the width of the channel section. In the Fin-type transistor, the height of the perpendicularly standing plate corresponds to the width of a normal planar transistor. However, increasing this height is not easy from the processing point of view. For this reason, if a large current is needed, it is desirable to use a multi-fin structure in which several fins are combined. Another problem is related to a high parasite resistance of the source-drain section of the transistor. This occurs because, when the perpendicularly standing source-drain is ion-implanted, dopants are difficult to reach the bottom thereof. In particular, in the multi-fin case, doping is more difficult because of shading by adjacent transistors.

As a technique for reducing the parasite resistance of the source-drain section, JP-A 2006-310772 (Kokai) discloses a recessed (etched) structure of the source-drain section. In this structure, dopants can be definitely implanted in the source-drain section, and the parasite resistance can be reduced.

### SUMMARY OF THE INVENTION

According to an aspect of the invention, there is provided a semiconductor apparatus including: a support substrate made of a semiconductor; an insulating layer provided on the support substrate and having a first and a second openings; a semiconductor fin having a channel section provided upright on the insulating layer between the first and the second openings, a first buried region provided in the first opening, a second buried region provided in the second opening, a source section provided on the first buried region and connected to the channel section, and a drain section provided on the second buried region and connected to the channel section; a gate insulating film covering a side face of the channel section, the side face being substantially parallel to a direction along which the source section and the drain section are provided; and a gate electrode opposed to the side face of the channel section across the gate insulating film.

According to another aspect of the invention, there is provided a semiconductor apparatus including: a support substrate made of a semiconductor; an insulating layer provided on the support substrate and having a first and a second openings; a semiconductor fin having a channel section provided upright on the insulating layer between the first and the second openings, a source section protruding upward from the support substrate through the first opening and connected to the channel section, and a drain section protruding upward from the support substrate through the second opening and connected to the channel section; a gate insulating film covering a side face of the channel section, the side face being substantially parallel to a direction along which the source section and the drain section are provided; and a gate electrode opposed to the side face of the channel section across the gate insulating film.

According to another aspect of the invention, there is provided a method for manufacturing a semiconductor apparatus, including: in a laminated body including a support substrate made of a semiconductor, an insulating layer provided on the support substrate, and a first semiconductor layer provided on the insulating layer, selectively removing the first semiconductor layer and the insulating layer to form a channel section made of the first semiconductor layer provided upright on the insulating layer, and exposing the support substrate on both sides of the channel section; and forming a source-drain section by growing a second semiconductor layer on the exposed support substrate so that the second semiconductor layer is connected to the channel section adjacent thereto.

According to another aspect of the invention, there is provided a method for manufacturing a semiconductor apparatus, including: in a laminated body including a support substrate made of a semiconductor, an insulating layer provided on the support substrate, and a semiconductor layer provided on the insulating layer, selectively removing the semiconductor layer and the insulating layer to form a channel section made of the semiconductor layer provided upright on the insulating layer, and exposing the support substrate on both sides of the channel section; depositing a metal film on the exposed support substrate; and forming a source-drain section by alloying the metal film with the support substrate to grow a silicide so that the silicide is connected to the channel section adjacent thereto.

### BRIEF DESCRIPTION OF THE DRAWINGS

FIGS. 1A through 1C include conceptual views showing a semiconductor apparatus according to an embodiment of the invention.

FIGS. 2A through 2C are process views illustrating a method for manufacturing a semiconductor apparatus of this embodiment.

FIGS. 3A through 3C are process views illustrating a method for manufacturing a semiconductor apparatus of this embodiment.

FIG. 4 is a process view illustrating a method for manufacturing a semiconductor apparatus of this embodiment.

FIGS. 5A through 5C are process views illustrating a method for manufacturing a semiconductor apparatus of this embodiment.

FIGS. 6A through 6C are process views illustrating a method for manufacturing a semiconductor apparatus of this embodiment.

FIGS. 7A through 7C are process views illustrating a method for manufacturing a semiconductor apparatus of this embodiment.

FIGS. 8A through 8C are process views illustrating a method for manufacturing a semiconductor apparatus of this embodiment.

FIGS. 9A through 9C are process views illustrating a method for manufacturing a semiconductor apparatus of this embodiment.

FIGS. 10A through 10C are schematic views showing a method for manufacturing a semiconductor apparatus of a comparative example.

FIGS. 11A and 11B are schematic views showing a method for manufacturing a semiconductor apparatus of a comparative example.

FIG. 12 is a cross-sectional view of the semiconductor apparatus of this embodiment.

FIGS. 13A through 13C are schematic views showing a variation of this embodiment.

FIG. 14 is a schematic view showing another variation of this embodiment.

FIG. 15 is a schematic view showing another variation of this embodiment.

FIGS. 16A through 16C are process views illustrating a method for manufacturing a semiconductor apparatus of this variation.

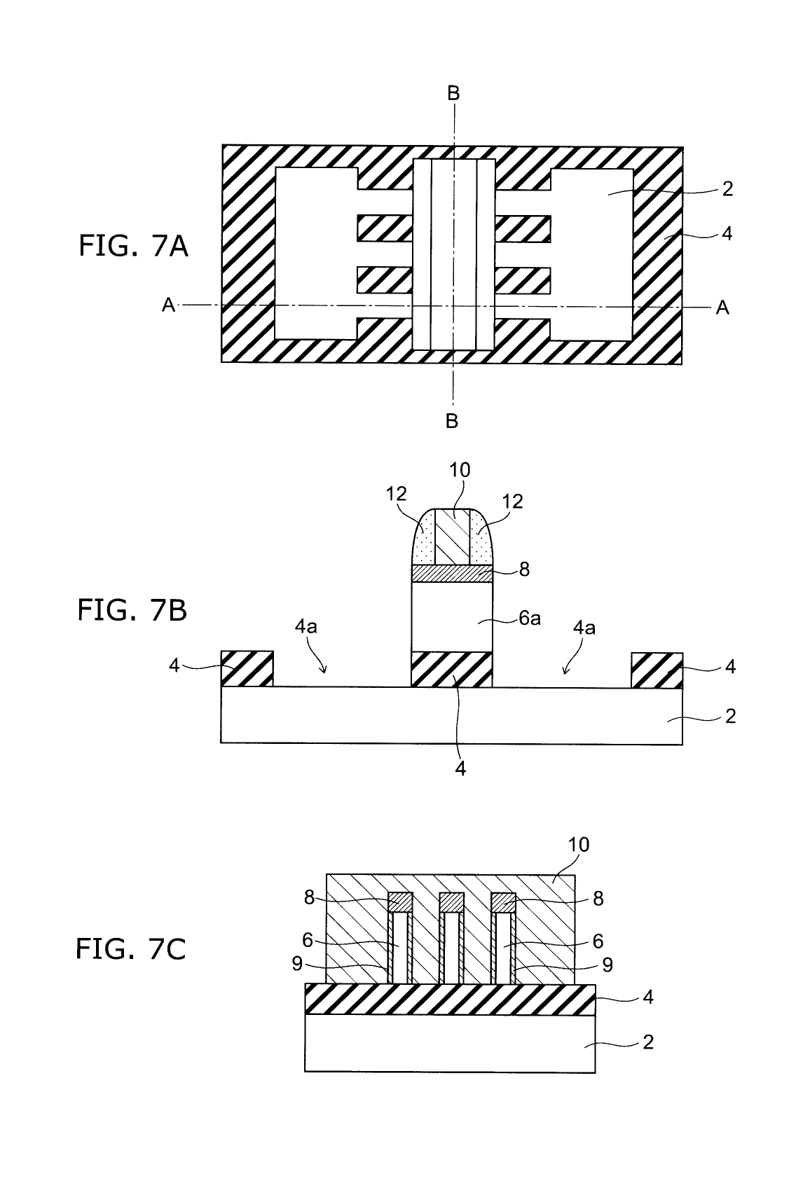

FIGS. 7A through 17C are process views illustrating a method for manufacturing a semiconductor apparatus of this variation.

### DETAILED DESCRIPTION OF THE INVENTION

An embodiment of the invention will now be described with reference to the drawings.

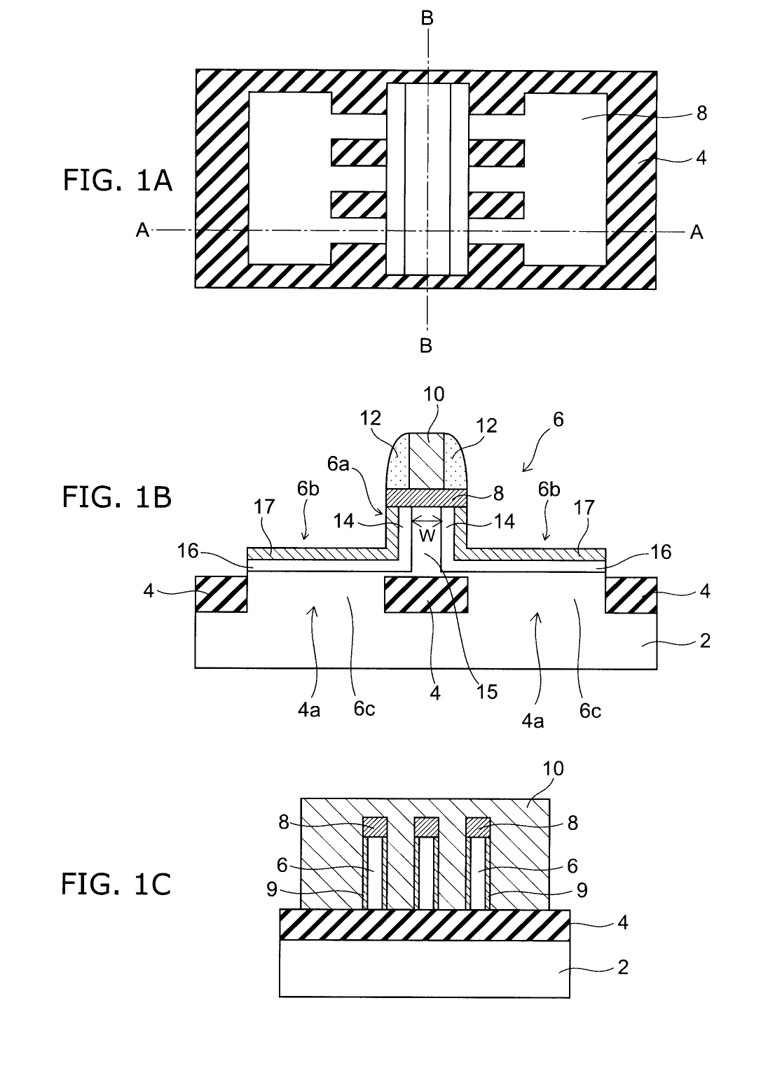

FIG. 1 includes conceptual views showing a semiconductor apparatus according to the embodiment of the invention. More specifically, FIG. 1A is a schematic plan view of the main part thereof, and FIGS. 1B and 1C are cross-sectional views taken along lines A-A and B-B of FIG. 1A, respectively.

The semiconductor apparatus of this example is a multi-fin transistor having a plurality of fins. An insulating layer 4 is provided on a support substrate 2 of p-type silicon. Semiconductor fins 6 are provided upright on the insulating layer 4. The semiconductor fin 6 includes a high-profile channel section 6a provided in the vicinity of the center and low-profile source-drain sections 6b extending on both sides thereof. The channel section 6a is provided on the insulating layer 4. On the other hand, an opening 4a is formed in the underlying insulating layer 4, and the source-drain section 6b is connected to the support substrate 2 through a buried region 6c provided in the opening 4a. The “semiconductor” used herein also includes silicides, which are alloys of silicon and metals.

The source-drain section 6b includes an n⁺-type diffusion region 16 doped with n-type impurities and a silicide region 17 formed on its frontside. The diffusion region 16 continues to an impurity region 14 formed along the side face of the channel section 6a to which the source-drain section 6b is connected. The silicide region 17 also extends along the side face of the channel section 6a. In the channel section 6a, a channel region 15 is provided between the impurity regions 14 on both sides.

A gate insulating film 9 is provided on the side face of the channel section 6a, and a channel protective film 8 is provided on the channel section 6a. The side face on which the gate insulating film 9 is provided is substantially parallel to a direction along which the source section 6b and the drain section 6b are provided. The channel section 6a is surrounded by a common gate electrode 10, which extends and is provided upright in a direction generally orthogonal to the extending direction of the plurality of semiconductor fins 6. On the channel protective film 8, the gate electrode 10 is sandwiched on both sides thereof between insulative gate sidewalls 12.

In the semiconductor apparatus of this embodiment, the source-drain sections 6b extending on both sides of the channel section 6a have a lower profile than the channel section 6a. That is, the source-drain sections 6b are recessed relative to the channel section 6a.

According to this configuration, impurities can be sufficiently introduced into the source-drain section 6b down to its bottom to form a diffusion region 16. Consequently, the parasite resistance can be decreased. Simultaneously, the spacing W between the impurity regions 14 provided on both sides of the channel region 15 can be kept substantially constant from the upper end of the channel section 6a to the vicinity of the insulating layer 4. That is, the channel length can be made constant, and variation in the operation characteristics of the transistor can be reduced.

Furthermore, according to this embodiment, an opening 4a is formed in the insulating layer 4, and a source-drain section 6b is formed thereon. Thus a Fin-type transistor with a recessed source-drain section 6b can be steadily formed.

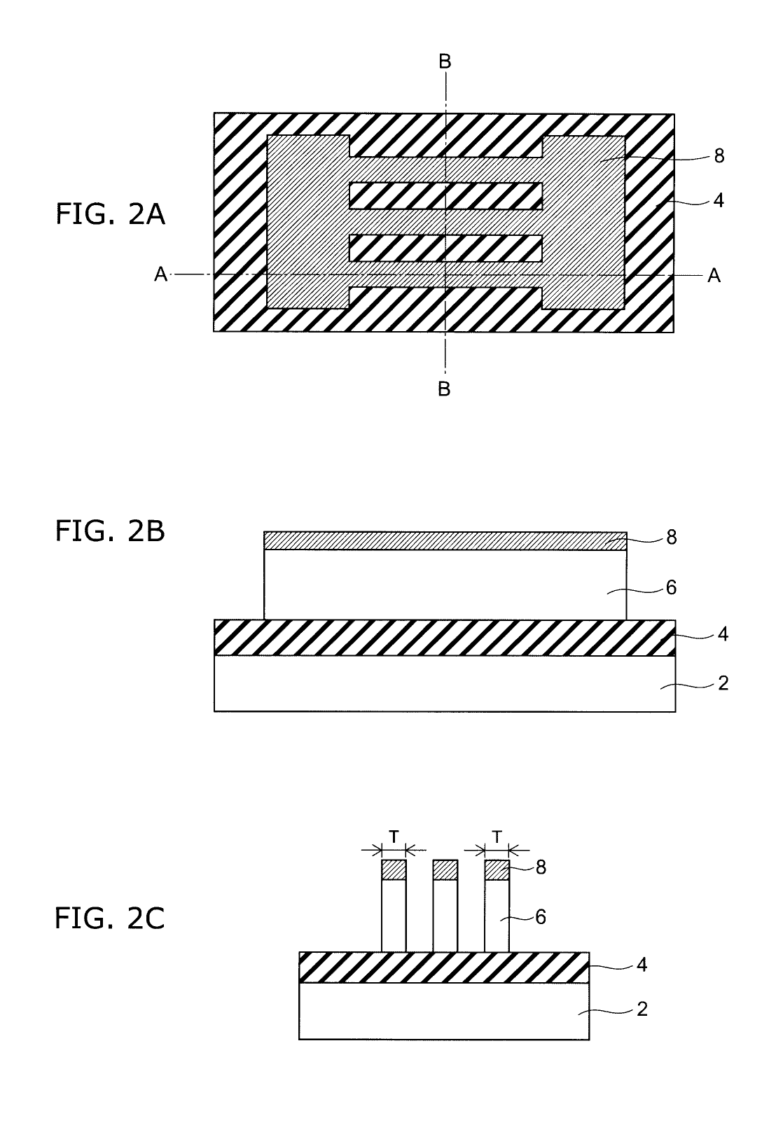

FIGS. 2 to 9 are process views illustrating a method for manufacturing a semiconductor apparatus of this embodiment.

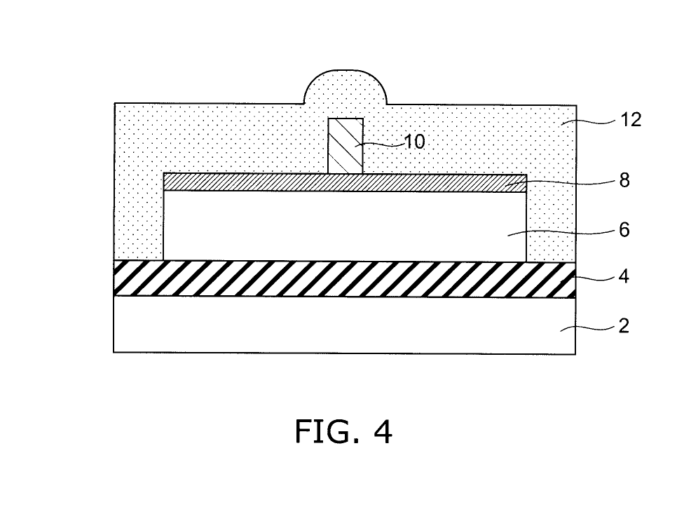

In FIGS. 2, 3, 5 to 9, the figure labeled with the suffix A is a schematic plan view of the main part thereof, and the figures labeled with the suffixes B and C are cross-sectional views taken along lines A-A and B-B of the figure labeled with the suffix A, respectively. FIG. 4 is a cross-sectional view corresponding to the A-A cross section. In FIG. 2 and the following figures, the same elements as those shown in the previous figures are marked with like reference numerals, and the detailed description thereof is omitted accordingly.

While an example of manufacturing an n-type channel transistor is described herein, a p-type channel transistor can be manufactured similarly.

First, as shown in FIG. 2, an SOI substrate is prepared by forming an insulating layer 4 on a support substrate 2 and forming an SOI layer on the insulating layer 4. A channel protective film 8 of silicon nitride is deposited by LPCVD (low pressure chemical vapor deposition) to approximately 100 nm. Then device isolation is performed by a device isolation technique. Furthermore, the SOI layer 6 is patterned to form semiconductor fins 6 serving as a channel. The thickness T of the semiconductor fin can be set to e.g. approximately 10 nm.

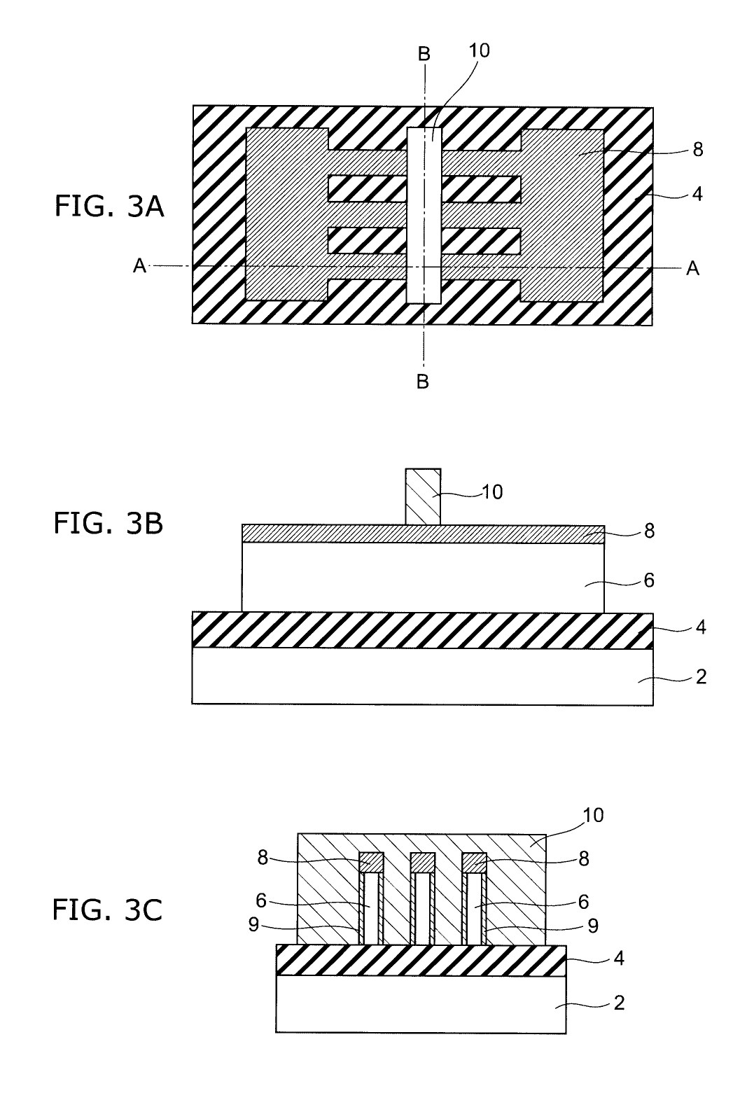

Next, as shown in FIG. 3, a gate insulating film 9 of silicon dioxide having a thickness of approximately 1 nm is formed by RTO (rapid thermal oxidation), and then subjected to plasma nitridation to increase its dielectric constant. It is also possible to form the gate insulating film 9 from high-k (high dielectric) materials having a higher dielectric constant, such as hafnium silicate (HfSiO, HfSiON), hafnium aluminate (HfAlO, HfAlON), HfO₂, Y₂O₃, lanthanum aluminate (LaAlO), and lanthanum hafnate (LaHfO).

Subsequently, a polysilicon film to serve as a gate electrode 10 is deposited by LPCVD to a thickness of approximately 100 nm. Further thereon, a hard mask layer (not shown) of silicon nitride film is deposited. Then photolithography is used to pattern this hard mask layer. Subsequently, the patterned hard mask layer is used as a mask to pattern the polysilicon layer by RIE, thereby forming a gate electrode 10. Here, an offset spacer may be further formed, but it is not shown in this example.

Next, as shown in FIG. 4, a silicon nitride layer to serve as a gate sidewall 12 is deposited by LPCVD to a thickness of approximately 100 nm.

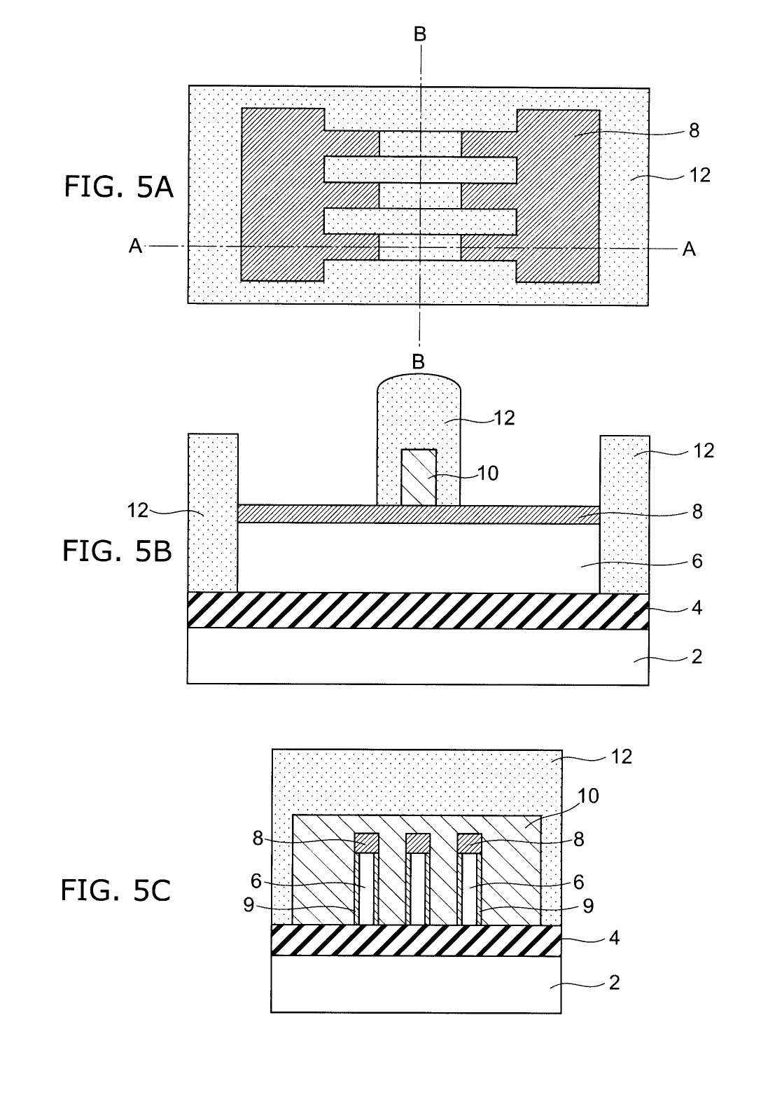

Then, as shown in FIG. 5, the silicon nitride layer 12 is patterned to form an opening only in the portion corresponding to the source-drain sections 6b (see FIG. 1).

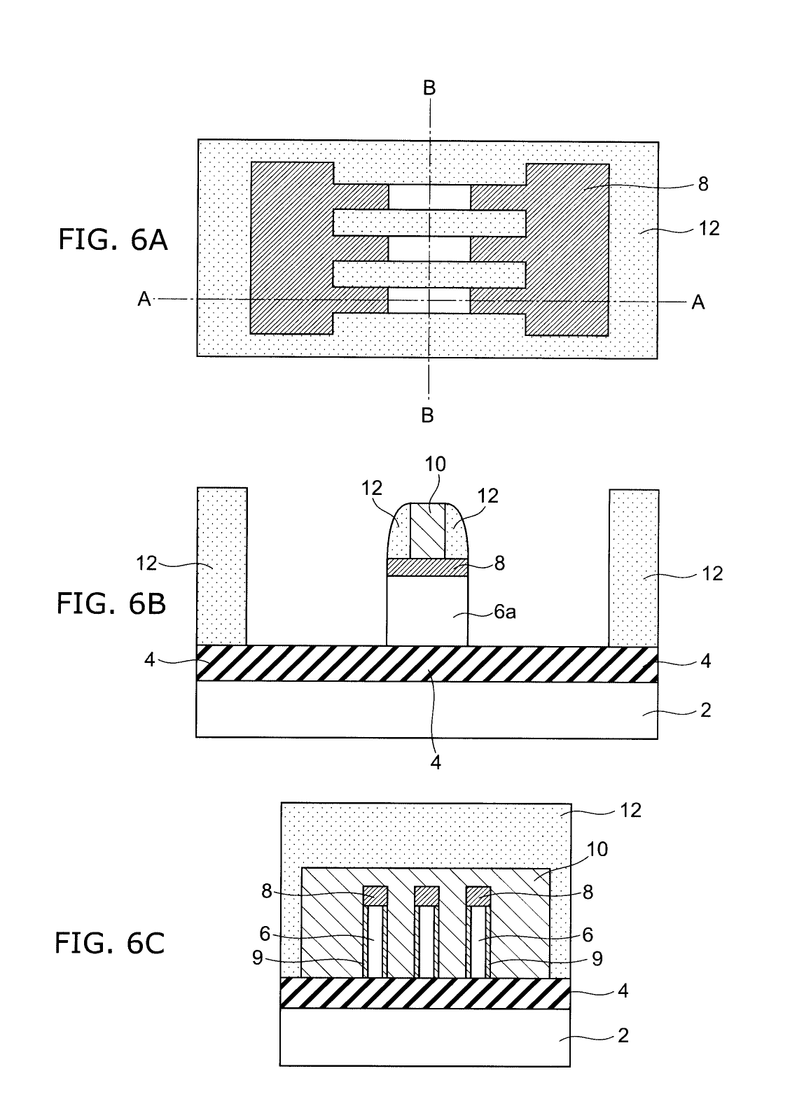

Subsequently, anisotropic etching such as RIE is used to perform etching vertically. By this etching, as shown in FIG. 6, a gate sidewall 12 is formed, and the SOI layer 6 in the portion corresponding to the source-drain sections 6b is removed to leave only a channel section 6a on the insulating layer 4. Here, if RIE is performed using a gas having a high selection ratio between Si and SiO₂, such as a mixed gas of NF₃, O₂, and SF₆ or a mixed gas of HBr, Cl₂, and O₂, then the insulating layer 4 acts as an etch stop layer, allowing accurate etching.

Then, as shown in FIG. 7, the insulating layer 4 exposed to the portion corresponding to the source-drain sections 6b (see FIG. 1) is etched to form an opening 4a, thereby exposing the support substrate 2. Also in this etching, if RIE is performed with a high selection ratio between Si and SiO₂, the support substrate 2 acts as an etch stop layer, allowing accurate etching.

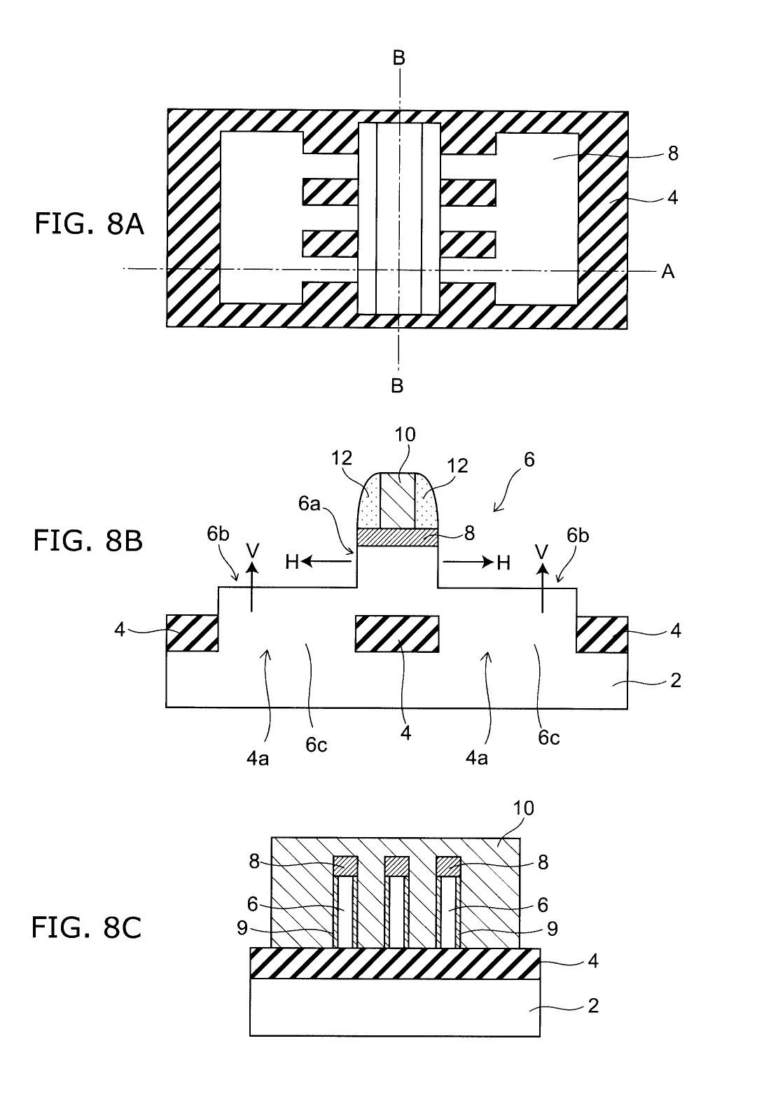

Next, as shown in FIG. 8, the support substrate 2 of silicon is used as a seed crystal to epitaxially grow silicon, thereby forming source-drain sections 6b. More specifically, a buried region 6c is formed in the opening 4a, and a source-drain section 6b is formed further thereon. Here, if the major surface of the underlying support substrate 2 exposed to the opening 4a of the insulating layer 4 has the (100) Si surface orientation, and the Fin-type channel transistor has the typical <110> channel direction, then the side face of the channel section 6a (the side face adjacent to the source-drain sections 6b) has the (110) Si surface orientation. Typically, the growth rate on the (100) Si surface is greater than the growth rate on the (110) Si surface. In the case of vapor-phase epitaxial growth, the growth rate on the (100) Si surface can be made ten times or more the growth rate on the (110) Si surface.

That is, the growth rate V of silicon growing upward from the surface of the support substrate 2 exposed to the opening 4a of the insulating layer 4 is higher than the growth rate H of silicon growing laterally from the side face of the channel section 6a. Consequently, without substantially varying the width of the channel section 6a, the source-drain sections 6b can be selectively grown. Furthermore, it is also possible to prevent disturbance in crystallinity at the junction between the channel section 6a and the source-drain sections 6b.

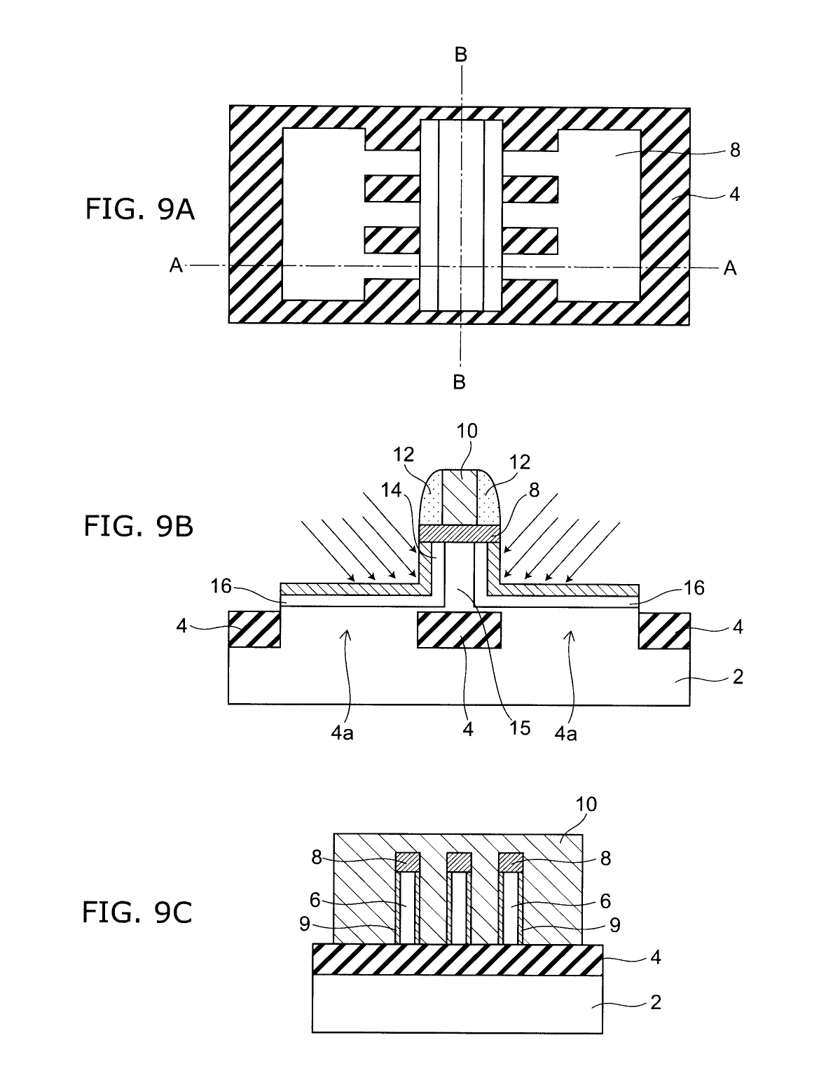

Next, as shown in FIG. 9, a halo region is formed by ion implantation of boron at 1 keV with approximately 1×10¹⁴ cm⁻², and then an extension region is formed by ion implantation of arsenic at 0.5 keV with approximately 2×10¹⁵ cm², thereby forming a pair of impurity regions 14 to serve as part of the source-drain. Furthermore, an n⁺-type diffusion region 16 is formed by ion implantation of arsenic at 30 keV with approximately 3×10¹⁵ cm⁻². As described above with reference to FIG. 1, the portion of the channel section 6a between the pair of impurity regions 14 serves as a channel region 15.

Subsequently, a high melting point metal such as nickel is sputtered, followed by heat treatment. Thus a self-aligned silicide region 17 is formed in the channel section 6a and the source-drain sections 6b, and simultaneously a self-aligned full silicide gate electrode is formed. Here, the diffusion region 16 acting as the source-drain may be entirely silicidized, or only partly silicidized.

It is noted that each ion implantation step is followed by activation annealing or other step as needed, the description of which is omitted in the foregoing. The halo region is not necessarily needed, but is preferable for preventing the short channel effect.

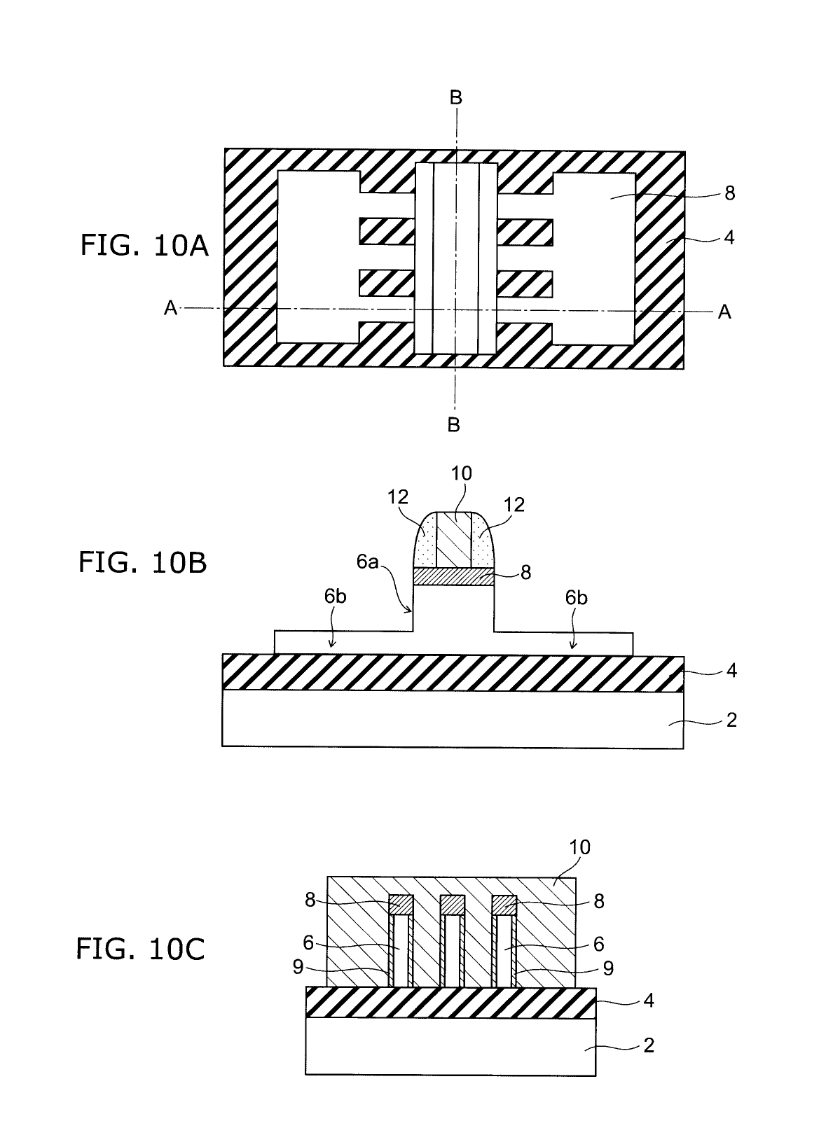

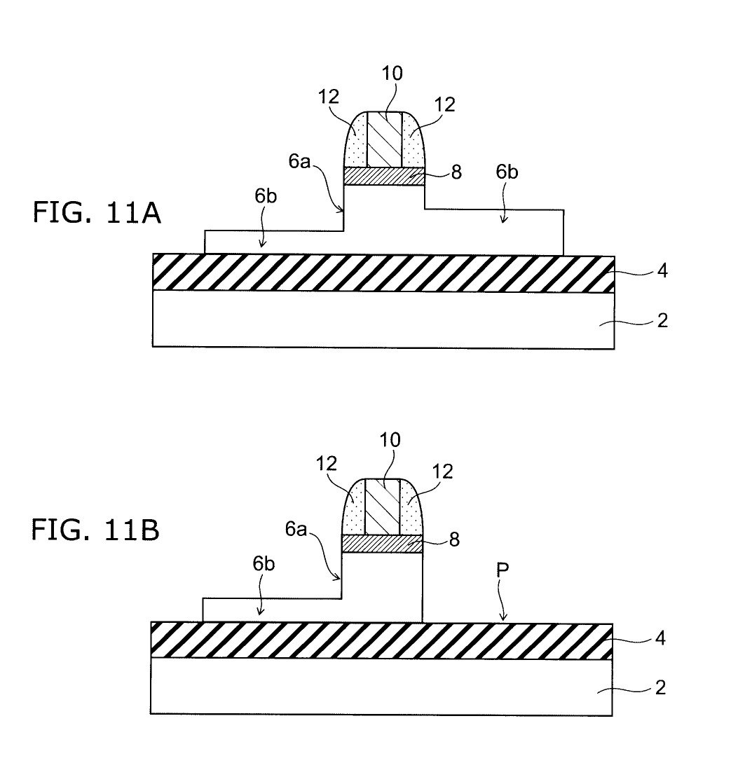

FIGS. 10 and 11 are schematic views showing a method for manufacturing a semiconductor apparatus of a comparative example.

In this comparative example, the SOI layer 6 is etched to form recessed source-drain sections 6b. More specifically, as described above with reference to FIG. 4, a silicon nitride layer 12 is deposited and etched vertically by anisotropic etching such as RIE. Thus a gate sidewall 12 is formed above the channel section 6a. Furthermore, by etching the SOI layer in the source-drain section 6b, a recessed source-drain section 6b can be formed as shown in FIG. 10.

However, in this method, the source-drain section 6b has no etch stop layer for controlling the height thereof. Hence it is not easy to control the height of the source-drain section 6b formed by etching. While the height H1 of the channel section 6a is set to e.g. approximately 100 nm, the height H2 of the source-drain section 6b is preferably kept below approximately 20 nm for definitely introducing impurities into the source-drain section 6b down to its bottom. However, if the source-drain section 6b is formed by etching as in this comparative example, the SOI layer of 100 nm needs to be etched to approximately 20 nm. Because of the large etching amount, the source-drain section 6b is likely to suffer variations in height.

Consequently, for example, the height of the source-drain sections 6b may differ between both sides of the channel section 6a as shown in FIG. 11A, or the source-drain section 6b may be overetched to result in a disconnection P as shown in FIG. 11B.

In contrast, according to this embodiment, as described above with reference to FIGS. 7 and 8, an opening 4a is formed in the insulating layer 4, and source-drain sections 6b are formed by epitaxially growing silicon from the exposed support substrate 2. In this method, the height of the source-drain section 6b can be definitely and easily controlled by epitaxial growth. As a result, for example, the source-drain section 6b can be steadily formed to a height of approximately 20 nm while the height of the channel section 6a is set to approximately 100 nm. Consequently, it is possible to steadily obtain a Fin-type channel transistor with reduced parasite resistance by definitely introducing impurities into the source-drain section 6b down to its bottom.

Next, a description is given of current leakage through the opening 4a formed in the insulating layer 4.

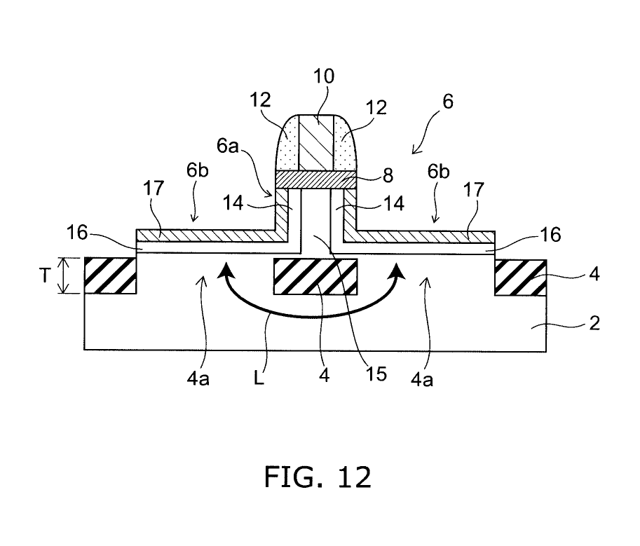

As shown in FIG. 12, the semiconductor apparatus of this embodiment has an opening 4a in the insulating layer 4. Hence, as shown by arrow L, leakage may occur between the source and the drain through the opening 4a. However, if the thickness T of the insulating layer 4 is set to generally 0.5 to 1.0 micrometer or more, for example, then the conductance of the current path shown by the arrow L is sufficiently small, and the current leakage is negligible.

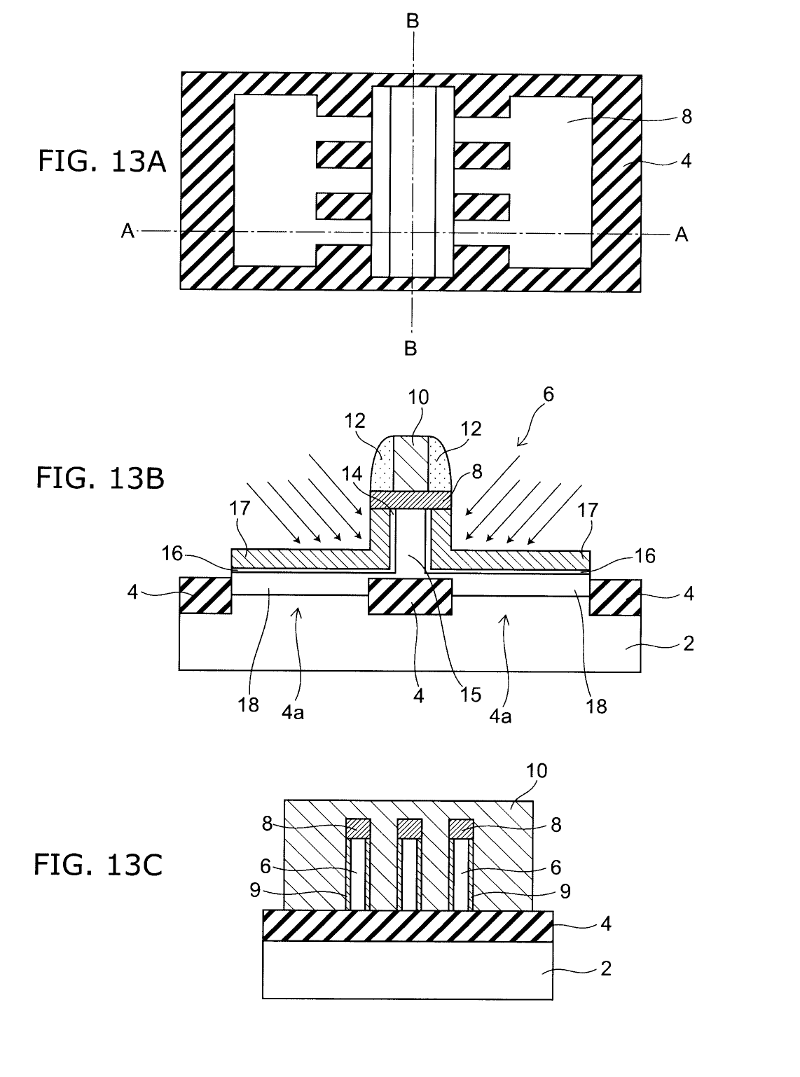

FIG. 13 is a schematic view showing a variation of this embodiment.

This variation includes a field-effect transistor having a source-drain of the metal-semiconductor junction type based on impurity segregation (segregated Schottky transistor). More specifically, the source-drain section 6b has a structure in which a silicide region 17 is formed above the halo region 18. This structure can be formed by adjusting the acceleration voltage of ion implantation for forming the extension region described above with reference to FIG. 9B and the deposition thickness of nickel for silicide formation.

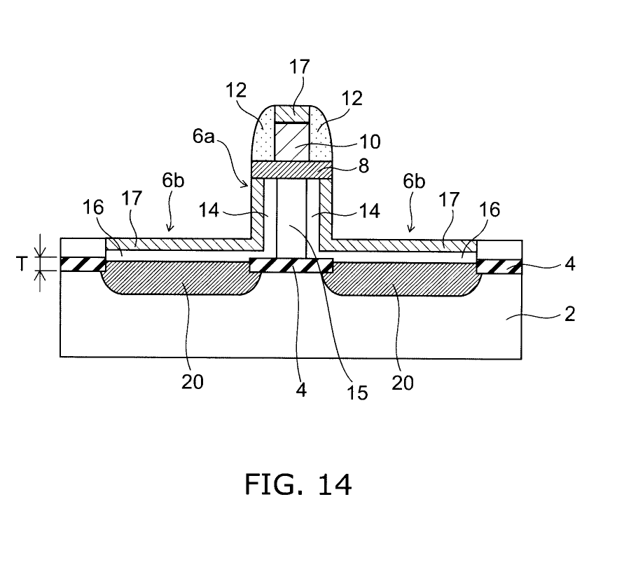

FIG. 14 is a schematic view showing another variation of this embodiment. That is, this figure is a cross-sectional view corresponding to FIG. 1B.

In this variation, a p⁺-type stopper region 20 is provided below the n⁺-type diffusion region 16 of the source-drain section 6b. This stopper region 20 can be formed by, for example, forming an opening 4a as described above with reference to FIG. 7 and then introducing p-type impurities into the support substrate 2 through the opening 4a.

The stopper region 20 in this variation blocks the depletion layer from extending from the diffusion region 16 toward the support substrate 2. That is, the stopper region 20 prevents current leakage due to punch-through in the support substrate 2. By providing such a stopper region 20, current leakage through the opening 4a can be prevented even if the thickness T of the insulating layer 4 is decreased.

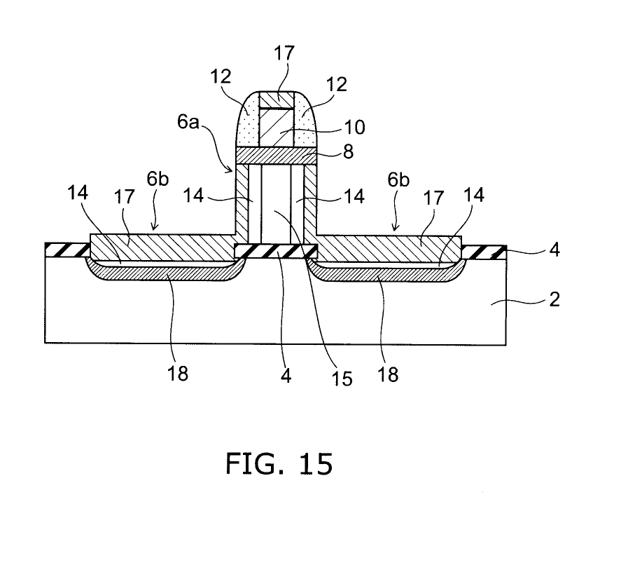

FIG. 15 is a schematic view showing another variation of this embodiment. That is, this figure is also a cross-sectional view corresponding to FIG. 1B.

In this variation, the silicide region 17 in the source-drain section 6b is formed so as to intrude into the opening 4a of the insulating layer 4. In this configuration, the parasite resistance can be further reduced. Also in this case, a p⁺-type stopper region 20 is provided below the n⁺-type diffusion region 16 to block the depletion layer from extending toward the support substrate 2. That is, the stopper region 20 prevents current leakage due to punch-through in the support substrate 2. By providing such a stopper region 20, current leakage through the opening 4a can be prevented even if the thickness T of the insulating layer 4 is decreased.

When the thickness of the insulating layer 4 is small, it is also possible to form the source-drain sections 6b simply by forming the silicide region 17 without epitaxial growth as described above with reference to FIG. 8.

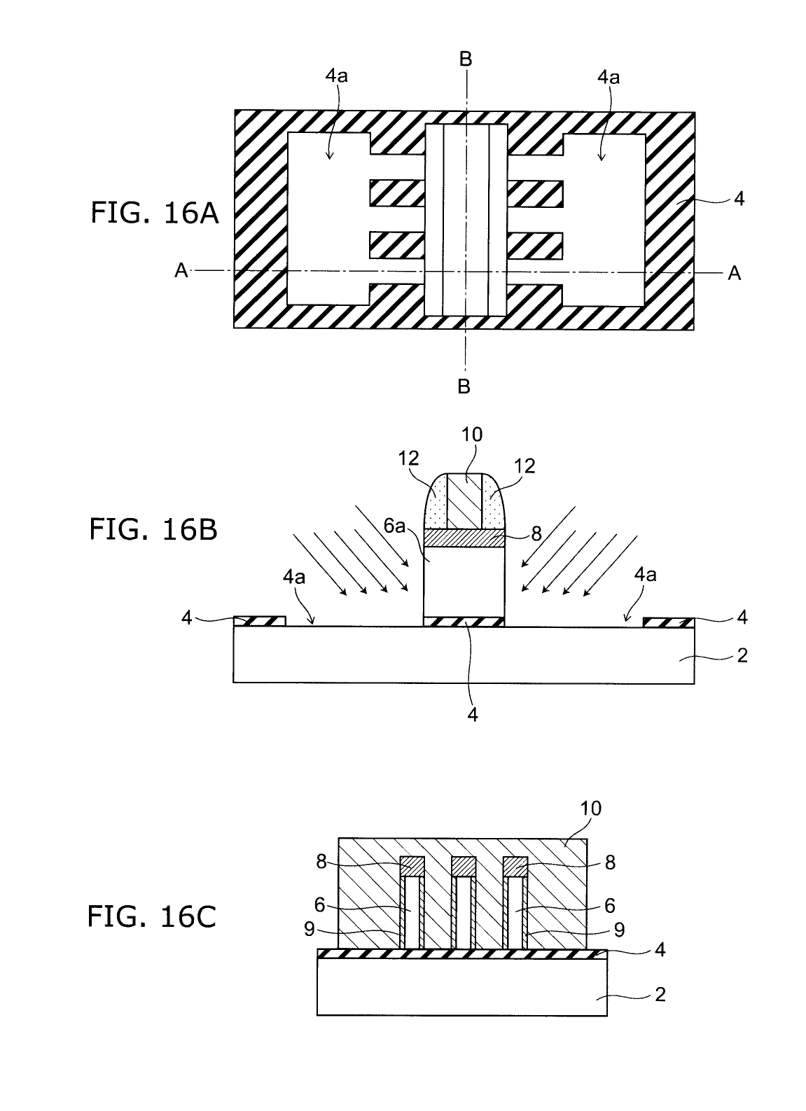

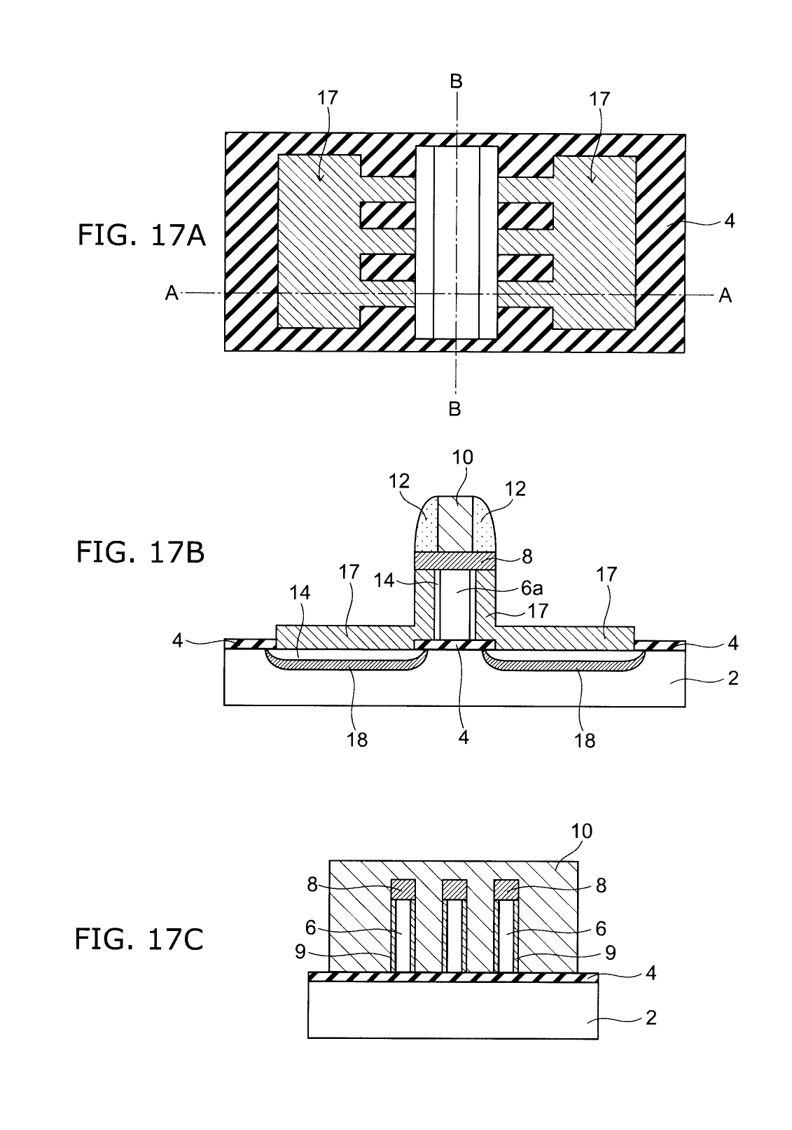

FIGS. 16 and 17 are process views illustrating a method for manufacturing a semiconductor apparatus of this variation.

More specifically, as shown in FIG. 16, an opening 4a is formed in the insulating layer 4 to expose the support substrate 2. This step is similar to that described above with reference to FIG. 7. Specifically, a silicon nitride layer deposited to a thickness of 100 nanometers, for example, is patterned so as to entirely mask the outside of the source-drain section. Then the insulating layer 4 is etched until the support substrate 2 is exposed. Here, by using RIE having a high selection ratio between silicon oxide constituting the insulating layer 4 and silicon constituting the support substrate 2, the insulating layer 4 and the support substrate 2 each serve as an etch stop layer, allowing accurate etching.

In this variation, the thickness of the insulating layer 4 is decreased. Specifically, while the thickness of the insulating layer 4 may be 100 nanometers or more in the case illustrated above with reference to FIGS. 1 to 9, it is preferable in this variation that the thickness of the insulating layer 4 be as small as around 10 nanometers.

After the opening 4a is thus formed, a halo region 18 is formed by ion implantation of impurities such as boron at an acceleration voltage of 1 kilovolt with approximately 1×10¹⁴ cm⁻², and then an extension region is formed by ion implantation of arsenic at an acceleration voltage of 0.5 kilovolts with approximately 1×10⁴ cm⁻², thereby forming a pair of impurity regions 14 to serve as part of the source-drain. The semiconductor layer 6a between this pair of impurity regions 14 serves as a channel region 15.

Subsequently, a high melting point metal such as nickel is deposited, followed by heat treatment. Thus a self-aligned silicide layer is formed in the surface of the semiconductor fin 6, and simultaneously a self-aligned full silicide gate electrode is formed.

Here, if the thickness of the insulating layer 4 is as small as approximately 10 nanometers, volume expansion due to silicidation results in bridging and connection between the silicide in the side face of the semiconductor layer 6a and the silicide on the support substrate 2. Thus epitaxial growth in the opening 4a of the insulating layer 4 can be omitted.

It is noted that activation annealing or other step is suitably performed after ion implantation in the process described above, but the description thereof is omitted. The halo region 18 is not necessarily needed, but is effective for preventing the short channel effect.

Also in this variation, as described above with reference to FIG. 13, a field-effect transistor having a source-drain of the metal-semiconductor junction type based on impurity segregation can be obtained by adjusting the acceleration voltage of ion implantation for forming the extension region and the deposition thickness of nickel or other metal for silicide formation.

Also in this variation, there occurs no variation due to etching as described above with reference to FIGS. 10 and 11, and a Fin-type transistor with reduced parasite resistance can be steadily formed. Furthermore, there is an additional advantage of simplifying the formation process because epitaxial growth through the opening 4a is not needed.

The embodiment of the invention has been described with reference to the examples. However, the invention is not limited to the above examples. For instance, two or more of the examples described above with reference to FIGS. 1 to 17 can be combined with each other as long as technically feasible, and such combinations are also encompassed within the scope of the invention.

This embodiment is not limited to multi-fin transistors having a plurality of fins. That is, the invention is also applicable to a Fin-type transistor having only a single fin to steadily form a structure having a recessed source-drain section 6b. Consequently, a Fin-type transistor with reduced parasite resistance can be obtained.

The invention can be practiced in various other modifications without departing from the spirit thereof, and all such modifications are encompassed within the scope of the invention.

1. A semiconductor apparatus comprising:
a support substrate made of a semiconductor;
an insulating layer provided on the support substrate and having a first and a second openings;
a semiconductor fin having a channel section provided upright on the insulating layer between the first and the second openings, a first buried region provided in the first opening, a second buried region provided in the second opening, a source section provided on the first buried region and connected to the channel section, and a drain section provided on the second buried region and connected to the channel section;
a gate insulating film covering a side face of the channel section, the side face being substantially parallel to a direction along which the source section and the drain section are provided; and
a gate electrode opposed to the side face of the channel section across the gate insulating film.

2. The semiconductor apparatus according to claim 1, wherein the height of the channel section with reference to the upper surface of the insulating layer is larger than the height of the source-drain section with reference to the upper surface of the insulating layer.

3. The semiconductor apparatus according to claim 1, wherein the source-drain section includes a silicide.

4. The semiconductor apparatus according to claim 1, wherein
the support substrate is of a second conductivity type,
the source-drain section is of a first conductivity type, and
a region of the support substrate facing to the source-drain section has a relatively high concentration of the second conductivity type.

5. The semiconductor apparatus according to claim 1, wherein
a plurality of the semiconductor fins are juxtaposed,
the gate insulating film is provided in each of the plurality of the semiconductor fins, and
the gate electrode is commonly opposed to the side face of the channel section of each of the plurality of the semiconductor fins across the gate insulating film.

6. The semiconductor apparatus according to claim 1, wherein
the major surface of the support substrate is a (100) surface, and
the side face of the channel section opposed to the source-drain section is a (110) surface.

7. The semiconductor apparatus according to claim 1, wherein a silicide intrudes into the opening of the insulating layer in the source-drain section.

8. A semiconductor apparatus comprising:
a support substrate made of a semiconductor;
an insulating layer provided on the support substrate and having a first and a second openings;
a semiconductor fin having a channel section provided upright on the insulating layer between the first and the second openings, a source section protruding upward from the support substrate through the first opening and connected to the channel section, and a drain section protruding upward from the support substrate through the second opening and connected to the channel section;
a gate insulating film covering a side face of the channel section, the side face being substantially parallel to a direction along which the source section and the drain section are provided; and
a gate electrode opposed to the side face of the channel section across the gate insulating film.

9. The semiconductor apparatus according to claim 8, wherein the height of the channel section with reference to the upper surface of the insulating layer is larger than the height of the source-drain section with reference to the upper surface of the insulating layer.

10. The semiconductor apparatus according to claim 8, wherein the source-drain section includes a silicide.

11. The semiconductor apparatus according to claim 8, wherein
the support substrate is of a second conductivity type,
the source-drain section is of a first conductivity type, and
a region of the support substrate facing to the source-drain section has a relatively high concentration of the second conductivity type.

12. The semiconductor apparatus according to claim 8, wherein
a plurality of the semiconductor fins are juxtaposed,
the gate insulating film is provided in each of the plurality of the semiconductor fins, and
the gate electrode is commonly opposed to the side face of the channel section of each of the plurality of the semiconductor fins across the gate insulating film.

13. The semiconductor apparatus according to claim 8, wherein
the major surface of the support substrate is a (100) surface, and
the side face of the channel section opposed to the source-drain section is a (110) surface.

14. The semiconductor apparatus according to claim 8, wherein a silicide intrudes into the opening of the insulating layer in the source-drain section.

15. A method for manufacturing a semiconductor apparatus, comprising:
in a laminated body including a support substrate made of a semiconductor, an insulating layer provided on the support substrate, and a first semiconductor layer provided on the insulating layer, selectively removing the first semiconductor layer and the insulating layer to form a channel section made of the first semiconductor layer provided upright on the insulating layer, and exposing the support substrate on both sides of the channel section; and
forming a source-drain section by growing a second semiconductor layer on the exposed support substrate so that the second semiconductor layer is connected to the channel section adjacent thereto.

16. The method according to claim 15, wherein in the forming a source-drain section, growth rate of the second semiconductor layer on the support substrate is higher than growth rate of the semiconductor layer on a side face of the channel section.

17. The method according to claim 15, wherein the height of the source-drain section with reference to the upper surface of the insulating layer is smaller than the height of the channel section with reference to the upper surface of the insulating layer.

18. A method for manufacturing a semiconductor apparatus, comprising:
in a laminated body including a support substrate made of a semiconductor, an insulating layer provided on the support substrate, and a semiconductor layer provided on the insulating layer, selectively removing the semiconductor layer and the insulating layer to form a channel section made of the semiconductor layer provided upright on the insulating layer, and exposing the support substrate on both sides of the channel section;
depositing a metal film on the exposed support substrate; and
forming a source-drain section by alloying the metal film with the support substrate to grow a silicide so that the silicide is connected to the channel section adjacent thereto.

19. The method according to claim 18, wherein the height of the source-drain section with reference to the upper surface of the insulating layer is smaller than the height of the channel section with reference to the upper surface of the insulating layer.

20. The method according to claim 18, wherein
the metal film is also deposited on a side surface of the channel section, and
a silicide grown on the side surface of the channel section and the silicide grown on the support substrate are connected.
